(19) United States
(12) Patent Application Publication
(10) Pub. No.: US 2026/0191060 A1
(43) Pub. Date: Jul. 2, 2026

(54) PACKAGE DEVICE WITH EMBEDDED SUBSTRATE INTEGRATED WAVEGUIDE STRUCTURE

(71) Applicant: Korea Electronics Technology Institute, Seongnam-si (KR)

(72) Inventors: Soo Chang CHAE, Suwon-si (KR); Jin Sup KIM, Seongnam-si (KR); Ki Jin KIM, Hwaseong-si (KR); Hyeon Bhin JO, Suwon-si (KR)

(73) Assignee: Korea Electronics Technology Institute, Seongnam-si (KR)

(21) Appl. No.: 19/434,167

(22) Filed: Dec. 29, 2025

(30) Foreign Application Priority Data
Dec. 30, 2024 (KR) 10-2024-0200987
Dec. 9, 2025 (KR) 10-2025-0193767

(51) Int. Cl. H10W 70/654; H10W 70/60; H10W 70/63; H10W 90/00

(52) U.S. Cl. CPC H10W 70/654; H10W 70/611; H10W 70/635; H10W 90/754

(57) ABSTRACT

Provided is a package device with a substrate integrated waveguide structure embedded therein. A package device according to an embodiment may include a substrate, a waveguide integrated into the substrate, and a semiconductor chip electrically connected with the waveguide, and the substrate, the waveguide, and the semiconductor chip may be integrated into the package device. Accordingly, the substrate integrated waveguide structure is embedded in an internal substrate of the package device, so that a signal transmission path is stably formed, minimizing signal loss and electromagnetic interference occurring in super-high frequency bands and enabling stable high-speed signal transmission.

### CROSS-REFERENCE TO RELATED APPLICATION(S) AND CLAIM OF PRIORITY

This application is based on and claims priorities under 35 U.S.C. § 119 to Korean Patent Application No. 10-2024-0200987, filed on December 30, 2024, and Korean Patent Application No. 10-2025-0193767, filed on December 9, 2025, in the Korean Intellectual Property Office, the disclosure of which is herein incorporated by reference in its entirety.

### BACKGROUND

### FIELD

The disclosure relates to a package device, and more particularly, to a package device for efficiently transmitting super-high frequency signals that are required in 5G/6G mobile communications.

### DESCRIPTION OF RELATED ART

With the recent development of 5G/6G mobile communications, needs for package technologies for enabling stable operation in super-high frequency bands are increasing. In such a next-generation communication environment, super-high speed data transmission, ultra-low latency characteristics, high signal integrity are required, and to achieve these, connection structures between semiconductor chips and package devices play an important role.

FIG. 1 is a view illustrating a related-art package device. As shown in FIG. 1, a structure for transmitting high speed signals in the related-art package device may include three lines in total, including a signal line S formed at the center and ground lines G positioned on both sides of the signal line S.

FIG. 2 is a view illustrating an interior structure of the package device shown in FIG. 1. As shown in FIG. 2, output pads of a semiconductor chip are also configured with a ground-signal-ground (G-S-G) structure like the line configuration, thereby minimizing signal loss and suppressing electromagnetic interference.

The G-S-G structure applied to the related-art package device attempts to reduce a noise and increase signal integrity by having ground lines G disposed on both sides of the signal line S. Such a package device of a transmission line structure of a microstrip type has the advantage of being relatively simple and easy to manufacture, but is reported as having the problems of great signal loss in super-high frequency bands, vulnerability to electromagnetic interference (EMI) between adjacent signal lines, low compatibility with other electronic devices, and low system stability.

In addition, as shown in FIG. 2, wire bonding is typically used in the process of connecting the semiconductor chip to the package device. However, when a bonding length becomes longer or uneven, parasitic inductance and parasitic capacitance components increase, resulting in degradation of signal transmission characteristics. This problem becomes more serious when semiconductor chips with difference sizes are integrated into a single package device.

As described above, the related-art transmission line-based package devices do not solve signal loss in super-high frequency bands and interference problems, and have difficulty in meeting the performance required by next-generation communication systems. Accordingly, there is a need for a package device with a new structure, particularly a structure that minimizes signal loss and is resistant to external interference.

### SUMMARY

The disclosure has been developed in order to solve the above-described problems, and an object of the disclosure is to provide a package device with a substrate integrated waveguide structure embedded in an internal substrate thereof, as a solution to minimize signal loss and electromagnetic interference occurring in super-high frequency bands and to enable stable high-speed signal transmission.

Another object of the disclosure is to provide a package device which introduces a transition structure to allow signal pads of a substrate integrated waveguide, which is wire-bonded to a semiconductor chip, to be progressively coupled to a main body, as a solution to compensate for parasitic components occurring when the semiconductor chip and the substrate integrated waveguide are connected, and to match impedance.

According to an embodiment of the disclosure to achieve the above-described objects, there is provided a package device including: a substrate; a waveguide integrated into the substrate; and a semiconductor chip electrically connected with the waveguide, wherein the substrate, the waveguide, and the semiconductor chip are integrated into the package device.

The waveguide may connect the semiconductor chip and an external element.

The waveguide may include: an upper metal layer bonded to an upper portion of the substrate; a lower metal layer bonded to a lower portion of the substrate, having a signal line disposed in a center thereof, and having ground lines disposed on both sides of the signal line; and vias penetrating through the substrate to connect both the ground lines of the lower metal layer and both edge areas of the upper metal layer.

The upper metal layer may include: a signal pad disposed at a distal end of the upper metal layer to be connected with a signal pad of the semiconductor chip; and ground pads disposed at a distal end of the upper metal layer to be connected with ground pads of the semiconductor chip, respectively.

The signal pad of the semiconductor chip and the signal pad of the upper metal layer may be connected to each other by a bonding wire, and the ground pads of the semiconductor chip and the ground pads of the upper metal layer may be connected to each other, respectively, by a bonding wire.

The upper metal layer may have a transition structure formed in an area between the pads of the upper metal layer and a main body of the upper metal layer to allow the signal pads of the upper metal layer to be progressively coupled to the main body of the upper metal layer.

The transition structure may be a tapered structure such that the signal pad progresses toward the main body of the upper metal layer and extends toward the ground pads to be connected with the ground pads.

The semiconductor chip may include: a first semiconductor chip mounted in a first area on the substrate; and a second semiconductor chip mounted in a second area on the substrate, and the waveguide may include: a first waveguide formed on the substrate to reach the first area to be electrically connected with the first semiconductor chip; and a second waveguide formed on the substrate to reach the second area to be electrically connected with the second semiconductor chip.

The semiconductor chip may include: a first semiconductor chip mounted in a first area on the substrate; and a third semiconductor chip mounted in a third area on the substrate, and the waveguide may include: a first waveguide formed on the substrate to reach the first area to be electrically connected with the first semiconductor chip; and a third waveguide having both ends formed on the substrate to reach the first area and the third area to electrically connect the first semiconductor chip and a third semiconductor chip.

According to another aspect of the disclosure, there is provided a package device including: a substrate; semiconductor chips mounted in different areas on the substrate, respectively; and a waveguide having both ends formed on the substrate to reach areas where the semiconductor chips are mounted to electrically connect the semiconductor chips.

As described above, according to embodiments of the disclosure, a substrate integrated waveguide structure is embedded in an internal substrate of a package device, so that a signal transmission path is stably formed, minimizing signal loss and electromagnetic interference occurring in super-high frequency bands and enabling stable high-speed signal transmission.

In addition, according to embodiments, a transition structure is introduced to allow signal pads of a substrate integrated waveguide, which is wire-bonded to a semiconductor chip, to be progressively coupled to a main body, so that parasitic inductance and impedance discontinuity occurring due to wire bonding may be compensated for, and hence, signal reflection may be minimized and impedance matching between the semiconductor chip and the package device may be facilitated.

Furthermore, according to embodiments of the disclosure, performance required in the next-generation super-high speed/ultra-low latency communication environments such as 5G/6G mobile communications is satisfied, providing an innovative packaging solution in the high frequency/high speed signal processing fields.

Other aspects, advantages, and salient features of the invention will become apparent to those skilled in the art from the following detailed description, which, taken in conjunction with the annexed drawings, discloses exemplary embodiments of the invention.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a view illustrating a related-art package device;

FIG. 2 is a view illustrating an interior structure of the package device illustrated in FIG. 1;

FIG. 3 is a view illustrating an interior structure of a package device according to an embodiment of the disclosure;

FIG. 4 is a view illustrating a structure of a substrate integrated waveguide in detail;

FIG. 5 is a view illustrating an interior structure of a package device according to another embodiment of the disclosure; and

FIG. 6 is a view illustrating an interior structure of a package device according to still another embodiment of the disclosure.

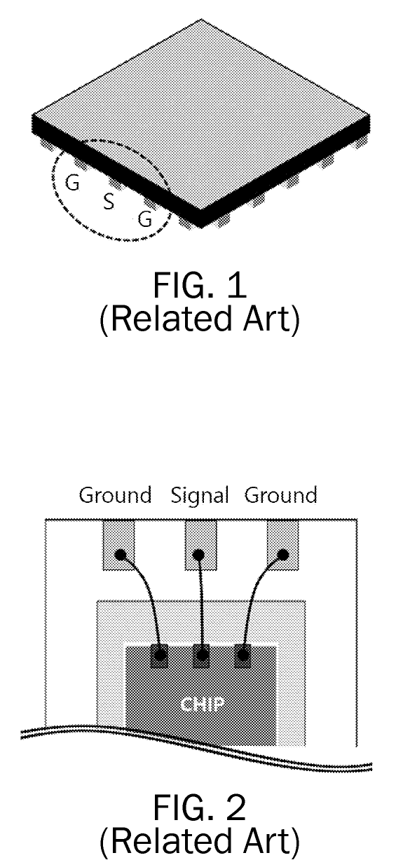

### DETAILED DESCRIPTION

Hereinafter, the disclosure will be described in more detail with reference to the accompanying drawings.

Embodiments of the disclosure propose a package device with a substrate integrated waveguide (SIW) embedded therein. The disclosure relates to a package device that has a 3-dimensional substrate integrated waveguide structure embedded in an internal substrate thereof, rather than a related-art two-dimensional transmission line, thereby having signal transmission paths stably formed to minimize signal loss and electromagnetic interference occurring in super-high frequency bands and to enable stable high speed signal transmission.

In addition, in embodiments of the disclosure, by introducing a transition structure to allow signal pads of a substrate integrated waveguide, which is wire-bonded to a semiconductor chip, to be progressively coupled to a main body, parasitic inductance occurring due to wire bonding may be compensated for and impedance matching between the semiconductor chip and the package device may be facilitated.

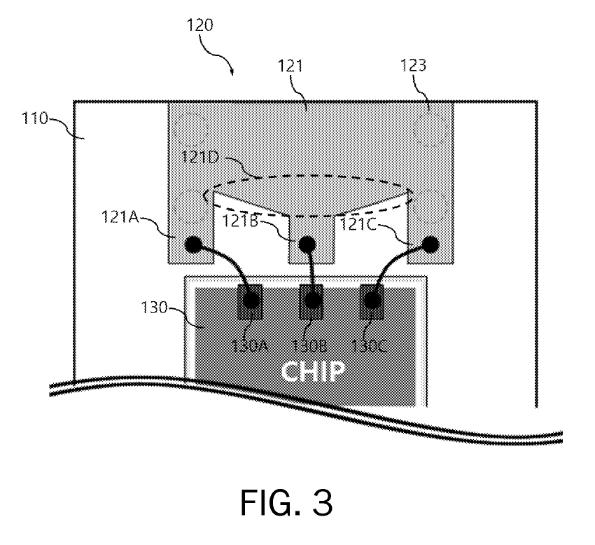

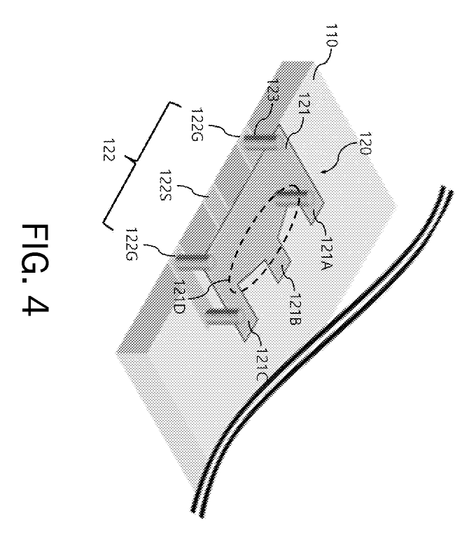

FIG. 3 is a view illustrating an interior structure of a package device according to an embodiment of the disclosure. As shown in FIG. 3, a substrate 110, a substrate integrated waveguide 120, and a semiconductor chip 130 are integrated in the package device according to an embodiment.

The substrate 110 has the semiconductor chip 130 mounted thereon and has an internal circuit and a wire formed therein, and is electrically connected with an external circuit. In addition, the substrate 110 has the substrate integrated waveguide 120 formed thereon.

The substrate integrated waveguide 120 is configured to transmit signals between the semiconductor chip 130 and an external element, and reinforces electromagnetic signal transmission performance in the package device, is resistant to external interference, and minimizes signal loss. FIG. 4 illustrates the structure of the substrate integrated waveguide 120 in detail.

As shown in FIG. 4, the substrate integrated waveguide 120 may include an upper metal layer 121, a lower metal layer 122, and vias 123. The upper metal layer 121 may be a metal plate that is bonded to an upper portion of the substrate 110. As shown in FIG. 3 in detail, the upper metal layer 121 may have input and output pads 121A, 121B, 121C which are formed on distal ends thereof to be wire-bonded to the semiconductor chip 130, and a transition structure 121D.

The lower metal layer 122 may be a metal plate that is bonded to a lower portion of the substrate 110, and may include a signal line 122S disposed at the center and ground lines 122G disposed on both sides as shown in FIG. 4.

The vias 123 penetrate through the substrate 110 to connect ground wires G on both sides of the lower metal layer 122 and edge areas of the upper metal layer 110. The vias 123 are arranged at defined intervals.

The substrate integrated waveguide 120 is a space that is surrounded by the upper metal layer 121, the lower metal layer 122, and the vias 123. This space is illustrated as being empty in FIG. 4, but actually, this space is filled with the substrate 110. FIG. 4 omits the substrate 110 of the inner space to clearly show the structure of the substrate integrated waveguide 120.

As shown in FIG. 3, input and output pads 130A, 130B, 130C of the semiconductor chip 130 and the input and output pads 121A, 121B, 121C formed on the upper metal layer 121 of the substrate integrated waveguide 120 may be connected to each other by wire bonding, such that the semiconductor chip 130 and the substrate integrated waveguide 120 are electrically connected to each other to enable signal transmission.

The connection structure between the semiconductor chip 130 and the substrate integrated waveguide 120 is a G-S-G connection structure. Specifically, the signal pad 130B of the semiconductor chip 130 is connected with the signal pad 121B of the substrate integrated waveguide 120, and the ground pads 130A, 130C of the semiconductor chip 130 are connected to the ground pads 121A, 121C of the substrate integrated waveguide 120, respectively.

The transition structure 121D is an area between the input and output pads 121A, 121B, 121C of the upper metal layer 121 and the main body of the upper metal layer 121, and is a structure that allows the signal pad 121B of the upper metal layer 121 to be progressively coupled to the main body of the upper metal layer 121.

Specifically, the transition structure 121D is formed in a tapered shape such that the signal pad 121B progresses toward the main body of the upper metal layer 121 and extends toward the ground pads 121A, 121C to be connected with the ground pads 121A, 121C.

The transition structure 121D may compensate for parasitic inductance components occurring due to wire bonding for connecting the semiconductor chip 130 and the substrate integrated waveguide 120, and may match the impedance between the semiconductor chip 130 and the substrate integrated waveguide 120, thereby minimizing signal reflection.

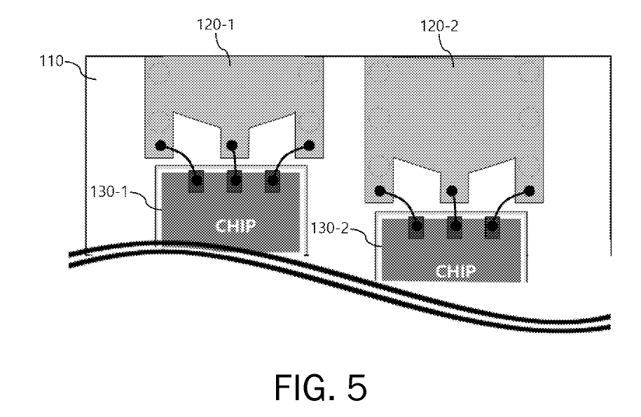

FIG. 5 is a view illustrating an interior structure of a package device according to another embodiment of the disclosure. The package device according to another embodiment may have two substrate integrated waveguides 120-1, 120-2 formed on a substrate 110, and two semiconductor chips 130-1, 130-2 mounted on the substrate 110.

The semiconductor chips 130-1, 130-2 on the substrate 110 have different chip sizes, and are mounted in different areas. The substrate integrated waveguides 120-1, 120-2 are configured to connect the semiconductor chips 130-1, 130-2 to external elements (not shown), respectively. Specifically, the substrate integrated waveguide-1 120-1 is a signal transmission path between the semiconductor chip-1 130-1 and an external element-1 (not shown), and the substrate integrated waveguide-2 120-2 is a signal transmission path between the semiconductor chip-2 130-2 and an external element-2 (not shown).

A distal end of the substrate integrated waveguide-1 120-1 is formed on the substrate 110 to reach an area where the semiconductor chip-1 130-1 is mounted, thereby being connected to the semiconductor chip-1 130-1 by a short bonding wire. Likewise, a distal end of the substrate integrated waveguide-2 120-2 is formed on the substrate 110 to reach an area where the semiconductor chip-2 130-2 is mounted, thereby being connected with the semiconductor chip-2 130-2 by a short bonding wire.

In the process of connecting semiconductor chips and transmission lines in a related-art package device, when the semiconductor chips are mounted in different areas due to their different sizes, the length of a bonding wire may become excessively longer on one side, and large parasitic components may occur due to the long length of the bonding wire, or signal loss may increase as the signal transmission distance increases. The embodiment proposed in FIG. 5 is for preventing such problems.

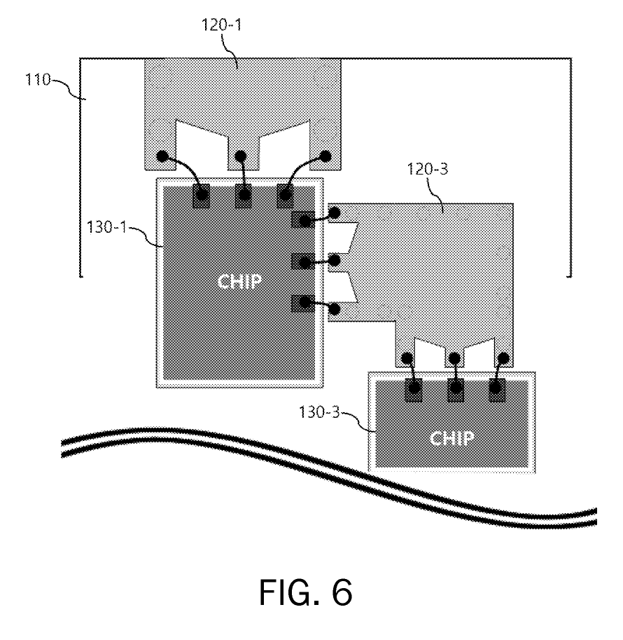

FIG. 6 is a view illustrating an interior structure of a package device according to still another embodiment of the disclosure. The package device according to still another embodiment may have two substrate integrated waveguides 120-1, 120-3 formed on a substrate 110, and two semiconductor chips 130-1, 130-3 mounted on the substrate 110.

The semiconductor chips 130-1, 130-3 are mounted in different areas on the substrate 110, and the semiconductor chip-1 130-1 is connected to an external element (not shown), whereas the semiconductor chip-3 130-3 is not connected to an external element. Specifically, only the semiconductor chip-1130-1 is connected to an external element (not shown) via the substrate integrated waveguide-1 120-1.

In the package device, the semiconductor chip-1 130-1 and the semiconductor chip-3 130-3 are connected to each other via the substrate integrated waveguide-3 120-3. That is, both ends of the substrate integrated waveguide-3 120-3 are formed on the substrate 110 to reach the mounting area of the semiconductor chip-1 130-1 and the mounting area of the semiconductor chip-3 130-3, respectively, thereby electrically connecting the semiconductor chip-1 130-1 and the semiconductor chip-3 130-3.

The structure proposed in FIG. 6 may be utilized in an application example such as an RF front end, and in this case, super-high frequency signals may be transmitted between the semiconductor chip-1 130-1 and the semiconductor chip-3 130-3 without loss and interference.

Up to now, a package device having a substrate integrated waveguide structure embedded therein has been described in detail with reference to preferred embodiments.

In the above embodiments, a substrate integrated waveguide structure is embedded in an internal substrate of a package device, so that a signal transmission path is stably formed, minimizing signal loss and electromagnetic interference occurring in super-high frequency bands and enabling stable high-speed signal transmission.

In addition, in the above embodiments, a transition structure is introduced to allow signal pads of a substrate integrated waveguide, which is wire-bonded to a semiconductor chip, to be progressively coupled to a main body, so that parasitic inductance and impedance discontinuity occurring due to wire bonding may be compensated for, and hence, signal reflection may be minimized and impedance matching between the semiconductor chip and the package device may be facilitated.

The technical concept of the disclosure may be applied to a computer-readable recording medium which records a computer program for performing the functions of the apparatus and the method according to the present embodiments. In addition, the technical idea according to various embodiments of the disclosure may be implemented in the form of a computer readable code recorded on the computer-readable recording medium. The computer-readable recording medium may be any data storage device that can be read by a computer and can store data. For example, the computer-readable recording medium may be a read only memory (ROM), a random access memory (RAM), a CD-ROM, a magnetic tape, a floppy disk, an optical disk, a hard disk drive, or the like. A computer readable code or program that is stored in the computer readable recording medium may be transmitted via a network connected between computers.

In addition, while preferred embodiments of the present disclosure have been illustrated and described, the present disclosure is not limited to the above-described specific embodiments. Various changes can be made by a person skilled in the at without departing from the scope of the present disclosure claimed in claims, and also, changed embodiments should not be understood as being separate from the technical idea or prospect of the present disclosure.

What is claimed is:

1. A package device comprising:
a substrate;
a waveguide integrated into the substrate; and
a semiconductor chip electrically connected with the waveguide,
wherein the substrate, the waveguide, and the semiconductor chip are integrated into the package device.

2. The package device of claim 1, wherein the waveguide is configured to connect the semiconductor chip and an external element.

3. The package device of claim 1, wherein the waveguide comprises:
an upper metal layer bonded to an upper portion of the substrate;
a lower metal layer bonded to a lower portion of the substrate, having a signal line disposed in a center thereof, and having ground lines disposed on both sides of the signal line; and
vias penetrating through the substrate to connect both the ground lines of the lower metal layer and both edge areas of the upper metal layer.

4. The package device of claim 3, wherein the upper metal layer comprises:
a signal pad disposed at a distal end of the upper metal layer to be connected with a signal pad of the semiconductor chip; and
ground pads disposed at a distal end of the upper metal layer to be connected with ground pads of the semiconductor chip, respectively.

5. The package device of claim 4, wherein the signal pad of the semiconductor chip and the signal pad of the upper metal layer are connected to each other by a bonding wire, and
wherein the ground pads of the semiconductor chip and the ground pads of the upper metal layer are connected to each other, respectively, by a bonding wire.

6. The package device of claim 4, wherein the upper metal layer has a transition structure formed in an area between the pads of the upper metal layer and a main body of the upper metal layer to allow the signal pads of the upper metal layer to be progressively coupled to the main body of the upper metal layer.

7. The package device of claim 6, wherein the transition structure is a tapered structure such that the signal pad progresses toward the main body of the upper metal layer and extends toward the ground pads to be connected with the ground pads.

8. The package device of claim 1, wherein the semiconductor chip comprises:
a first semiconductor chip mounted in a first area on the substrate; and
a second semiconductor chip mounted in a second area on the substrate, and
wherein the waveguide comprises:
a first waveguide formed on the substrate to reach the first area to be electrically connected with the first semiconductor chip; and
a second waveguide formed on the substrate to reach the second area to be electrically connected with the second semiconductor chip.

9. The package device of claim 1, wherein the semiconductor chip comprises:
a first semiconductor chip mounted in a first area on the substrate; and
a third semiconductor chip mounted in a third area on the substrate, and
wherein the waveguide comprises:
a first waveguide formed on the substrate to reach the first area to be electrically connected with the first semiconductor chip; and
a third waveguide having both ends formed on the substrate to reach the first area and the third area to electrically connect the first semiconductor chip and a third semiconductor chip.

10. A package device comprising:
a substrate;
semiconductor chips mounted in different areas on the substrate, respectively; and
a waveguide having both ends formed on the substrate to reach areas where the semiconductor chips are mounted to electrically connect the semiconductor chips.
